(19) United States
(12) Patent Application Publication
(10) Pub. No.: US 2025/0147082 A1
(43) Pub. Date: May 8, 2025

(54) A SYSTEM AND METHOD FOR MEASURING VOLTAGE IN MID CABLE

(71) Applicant: ELECTRICAL GRID MONITORING LTD., Rosh Haayin (IL)

(72) Inventor: Eyal Eliyahu MIRON, Hod Hasharon (IL)

(21) Appl. No.: 18/836,769

(22) PCT Filed: Feb. 9, 2023
(86) PCT No.: PCT/IB2023/051164

§ 371 Date: Aug. 8, 2024

Related U.S. Application Data
(60) Provisional application No. 63/308,075, filed on Feb. 9, 2022.

(51) Int. Cl. G01R 19/25; G01R 15/16; G01R 31/08; G01R 31/58

(52) U.S. Cl. CPC G01R 19/2506; G01R 15/16; G01R 31/083; G01R 31/58

(57) ABSTRACT

A system, a method, and/or a computer program for measuring voltage between an electric cable of an electric grid and a reference point, with no electric contact to the reference point. The voltage measuring device may include a first plate having a first area and providing a first capacitance between the first plate and the reference point, and a second plate having a second area and providing a second capacitance between the second plate and the reference point, at least one current measuring device for measuring current via the first plate and the second plate for providing respective first and second current measurements, and a processor electrically coupled to the current measuring device(s) for receiving the current measurements and for calculating the voltage between the electric cable and the reference point by comparing the current measurements between the reference point and each of the first plate and second plate.

### FIELD

The invention relates generally to the field of electric grids, and, more particularly but not exclusively, to electric transmission and distribution networks and, more particularly but not exclusively, to detecting faults in an electric grid by means of a sensor mounted on the electric cable, and, more particularly but not exclusively, to measuring various electrical parameters in mid cable.

### BACKGROUND

An electric grid may have many faults. Various components of the grid may fail, and a failure may be instantaneous, gradual, or intermittent. Some faults may be caused by the environment, such as humidity, smoke, dust, wind, trees, etc. Various faults and failures may have different characteristics and affect the network in different ways. Characterizing, detecting, identifying, and localizing faults in an electric grid is a known problem with various solutions including various types of sensors mounted on the cable of the electric grid.

One important parameter that needs to be measured is the electric voltage in various points in mid cable. Other important parameters associated with mid-cable voltage are capacitance between the cable and a reference point, reactance between the cable and a reference point, and impedance between the cable and a reference point, as measured in mid cable. The problem with measuring such parameters is that the measuring equipment, when mounted in mid cable, may not have an electric contact to the reference point, or the neutral line, or a common cable, or any other reference point for measuring a potential difference.

### SUMMARY

According to one exemplary embodiment of the invention there is provided a system, a method, and/or a computer program for measuring voltage between an electric cable of an electric grid and a reference point such as ground. Such exemplary embodiment of a voltage measuring device may include multiple plates, including a first plate having a first area and providing a first capacitance between the first plate and the reference point, and at least one second plate having a second area and providing a second capacitance between the second plate and the reference point. Such exemplary embodiment of a voltage measuring device may also include at least one current measuring device for measuring current via each of the first plate and the at least one second plate for providing respective first and second current measurements (or more), and a processor electrically coupled to the one or more current measuring devices for receiving the first and the second current measurements (or more) and for calculating the voltage between the electric cable and the reference point by comparing the first and the second current measurements, as well as currents via other plates if provided. According to another exemplary embodiment the voltage measuring device may be mounted on the electric cable of the electric grid, in mid cable, and may not electrically connected by wire to the ground or a similar reference point such as a common line or neutral line.

According to still another exemplary embodiment of the voltage measuring device the first plate and the second plate may be facing the reference point and may be curled so that the at least one of the first plate and the second plate faces the reference point when the voltage measuring device or the plates may move such as performing yaw, pitch and/or roll.

According to yet another exemplary embodiment of the voltage measuring device the first plate and the second plate may be interleaved with each other.

Further according to another exemplary embodiment of the voltage measuring device the voltage measuring device may additionally comprises an accelerometer and/or a gyro for measuring at least one of yaw, pitch and roll of the voltage measuring device and/or the plates. The processor of the voltage measuring device may then calculate the voltage between the electric cable and the reference point taking into account the measured yaw, pitch and/or roll.

Still further according to another exemplary embodiment of the voltage measuring device, the processor may monitor one or more relations between current measurements to detect a fault and/or weather condition such as humidity, rain, and ice.

Yet further according to another exemplary embodiment of the voltage measuring device the processor may use the current measurements, the calculated voltage between the electric cable and the reference point, and the capacitance between the plates and the reference point, to calculate high-speed changes of the voltage between the electric cable and the reference point.

Even further according to another exemplary embodiment the voltage measuring device may additionally include internal capacitance between each of the plates and the electric cable and a step in which the internal capacitance is measured in a laboratory and then used by the processor for calculating the voltage between the electric cable and the reference point.

Unless otherwise defined, all technical and scientific terms used herein have the same meaning as commonly understood by one of ordinary skill in the relevant art. The materials, methods, and examples provided herein are illustrative only and not intended to be limiting. Except to the extent necessary or inherent in the processes themselves, no particular order of steps or stages of methods and processes described in this disclosure, including the figures, is intended or implied. In many cases the order of process steps may vary without changing the purpose or effect of the methods described.

### BRIEF DESCRIPTION OF THE DRAWINGS

Various embodiments if the invention are described herein, by way of example only, with reference to the accompanying drawings. With specific reference now to the drawings in detail, it is stressed that the particulars shown are by way of example and for purposes of illustrative discussion of the embodiments only, and are presented in order to provide what is believed to be useful and readily understood description of the principles and conceptual aspects of the invention. In this regard, no attempt is made to show structural details of the embodiments in more detail than is necessary for a fundamental understanding of the invention, the description taken with the drawings making apparent to those skilled in the art how the several forms and structures may be embodied in practice.

In the drawings:

FIG. 1 is a simplified illustration of cable devices mounted on respective electric cables of an electric grid where each cable device includes a cable voltage measuring system;

FIG. 2 is a first, simplified electric diagram of the voltage measuring system including two plates of different sizes;

FIG. 3 is a second, more detailed, simplified electric diagram of voltage measuring system including two plates of different sizes;

FIG. 4A is a simplified illustration of a printed circuit board (PCB) that includes a pair of plates of different sizes;

FIG. 4B is a simplified illustration of a printed circuit board (PCB) that includes a pair of curved plates of different sizes;

FIG. 4C is a simplified illustration of a printed circuit board (PCB) that includes a pair of interleaved plates of different sizes;

FIG. 5 is a simplified illustration of a cut through a cable device mounted on an electric cable and including the voltage measuring system;

FIG. 6 is a simplified illustration of a side cut of box 36 showing the PCB (or the pair of plates) curved down;

FIG. 7 is a simplified illustration of a side cut of box 36 showing the PCB (or the pair of plates) curved up; and

FIG. 8 is a simplified illustration of a computational device included in a cable device mounted on an electric cable and including the processor for of the voltage measuring system for calculating cable voltage in mid cable.

### DETAILED DESCRIPTION

A method and a system are provided for measuring voltage between an electric cable and a reference point without the measuring device having an electric contact with the reference point for measuring a potential difference. The measuring device may be an electric sensor operative to measure one or more electric parameters. The measuring device may be mounted on the electric cable, anywhere in mid cable, which may be anywhere between two poles or between two insulators carrying or supporting the cable. The cable may be an overhead cable or an underground cable. For example, for an underground cable the measuring device may be placed in a location where the underground cable is exposed, and/or with no shield, such as in maintenance holes (manholes) or split points, etc.

The principles and operation of the system and method for measuring voltage of an electric cable in mid cable according to the several exemplary embodiments described herein may be better understood with reference to the following drawings and accompanying description.

Before explaining at least one embodiment in detail, it is to be understood that the embodiments are not limited in their application to the details of construction and the arrangement of the components set forth in the following description or illustrated in the drawings. Other embodiments may be practiced or carried out in various ways. Also, it is to be understood that the phraseology and terminology employed herein is for the purpose of description and should not be regarded as limiting.

In this document, an element of a drawing that is not described within the scope of the drawing and is labeled with a numeral that has been described in a previous drawing has the same use and description as in the previous drawings. Similarly, an element that is identified in the text by a numeral that does not appear in the drawing described by the text, has the same use and description as in the previous drawings where it was described.

The drawings in this document may not meant to be in any scale. Different Figs. may use different scales and different scales can be used even within the same drawing, for example different scales for different views of the same object or different scales for the two adjacent objects.

The measuring device may measure various electric parameter in a plurality of locations in an electric network and determine, by comparing a plurality of measurements, that a fault exists, the type or characteristic of the fault, and its location. One important electric parameter is the electric voltage at a point of the electric cable which may be in mid cable, which is at a distance from any pole or insulator supporting the cable, and that the voltage measuring device may not have any electric contact with a reference point such as ground, or zero or neutral, or common line, etc.

In this respect, the voltage measuring device may be electrically coupled to the electric cable as a first reference point for measuring potential difference (e.g., voltage), but may lack a second electric contact to a second reference point (namely, neutral, ground, common line, etc.)

The term ‘grid’, or ‘electric grid’, may refer to the electric transmission network and/or the electric distribution network, and to any part of such network between the power generating station, or stations, and the load, or the consumer.

The term ‘cable’, or ‘electric cable’, may refer to any single cable, or wire, or powerline, of the grid, such as a phase carrying cable.

The term ‘cable device’ may refer to any device to be mounted on or dismounted from an electric cable of a grid, including a sensor, a measuring device, a communication device, etc. As a non-limiting example, the cable device may derive power from the electric and/or magnetic field around the electric cable, where the electric and/or magnetic field may be generated by the electric current flowing in the electric cable.

The term ‘measurement’ or ‘electrical measurement’ may refer to any type of measurement of any electric parameter such as voltage, current, electric field, magnetic field, resistance, capacitance, inductance, electric charge, etc. The term ‘physical measurement’ or ‘mechanical measurement’ may refer to any type of measurement of any physical parameter other than electrical parameters. Such parameters may be temperature, wind, humidity, motion, height, (cable) depression, (cable) angle, etc. Such measurements are typically performed by a cable device mounted on an electric cable.

The term ‘mid cable’ may refer to any position or point along the electric cable in which the cable device, or voltage sensor, or voltage measuring device, may be mounted on the electric cable, and where the cable device, or voltage sensor, or voltage measuring device, may not have access or electric contact to a reference electric potential such as ground, zero line, common like, neutral line, etc.

The term ‘reference point’ may refer to any such reference electric potential such as ground, zero line, common like, neutral line, a powerline of a different phase, a reference plane, etc.

The term ‘electrically coupled’, or ‘electrically connected’, or simply ‘connected’ may refer to direct or indirect electric contact (galvanic contact).

The term ‘ungrounded voltage measurement’ may refer to measuring electric voltage, or electric potential, of an electric element, such as an electric cable, being a first electric reference point, without contacting a second electric reference point, such as reference point, zero voltage line, common line, neutral line, a power line of a different phase, etc. For simplicity, all such versions of the second electric reference point may be referred herein as ‘reference point’.

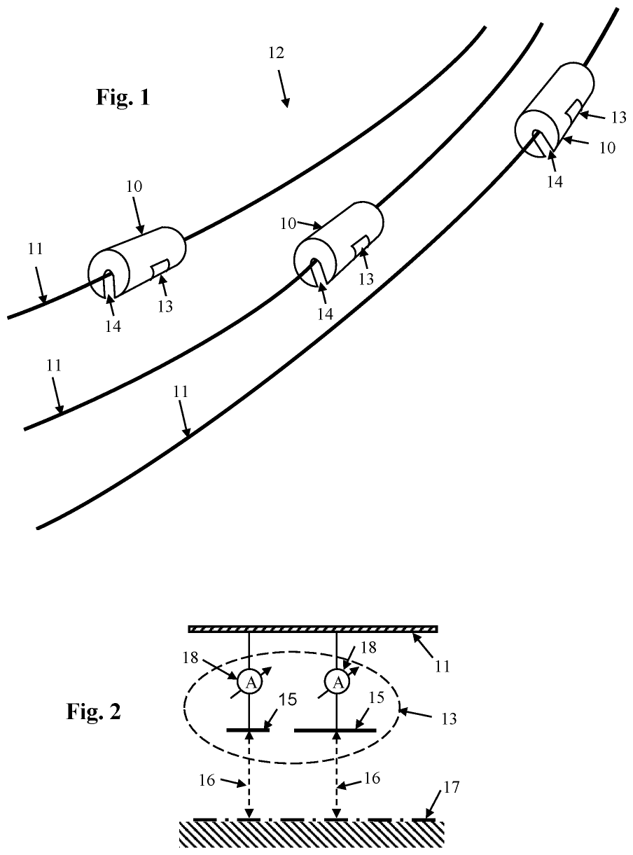

Reference is now made to FIG. 1, which is a simplified illustration of a cable devices 10 mounted on respective electric cables 11 of an electric grid 12 where each cable device 10 includes a cable voltage measuring system 13, according to one exemplary embodiment.

FIG. 1 shows three independent cable devices 10 mounted in three different places of respective cables 11 in mid cable. Cables 11 may be supported by poles (not shown), via insulators (not shown). FIG. 1 shows cables 11 between the poles or insulators. Each of the cable devices 10 may include a slot 14 or a similar arrangement through which cable 11 may be inserted into cable devices 10 when mounting cable devices 10 on a live cable 11. Each of the cable devices 10 includes a voltage measuring system as will be further described below.

As shown in FIG. 1, cable devices 10, and their respective voltage measuring systems 13, are coupled to their respective cables 11, but are not connected to any other reference point such as ground, zero voltage line, common line, neutral line, etc. In this respect voltage measuring system is an ungrounded voltage measuring system.

Reference is now made to FIG. 2, which is a first, simplified, electric diagram of voltage measuring system 13, according to one exemplary embodiment.

As an option, the simplified electric diagram of FIG. 2 may be viewed in the context of the details of the previous Figures. Of course, however, the simplified electric diagram of FIG. 2 may be viewed in the context of any desired environment. Further, the aforementioned definitions may equally apply to the description below.

As shown in FIG. 2, voltage measuring system 13 may include at least two electrically conductive plates 15 of different areas, the plates forming (external) parasitic capacitance 16 between each plate and ground reference point 17. A current measuring device 18, or a controlled current supply 18, is connected between electric cable 11 and each of plates 15. Voltage measuring system 13 may calculate the voltage between the plates 15 and the ground reference point 17 by comparing the two currents as measured by current measuring devices 18, or as provided by controlled current supplies 18.

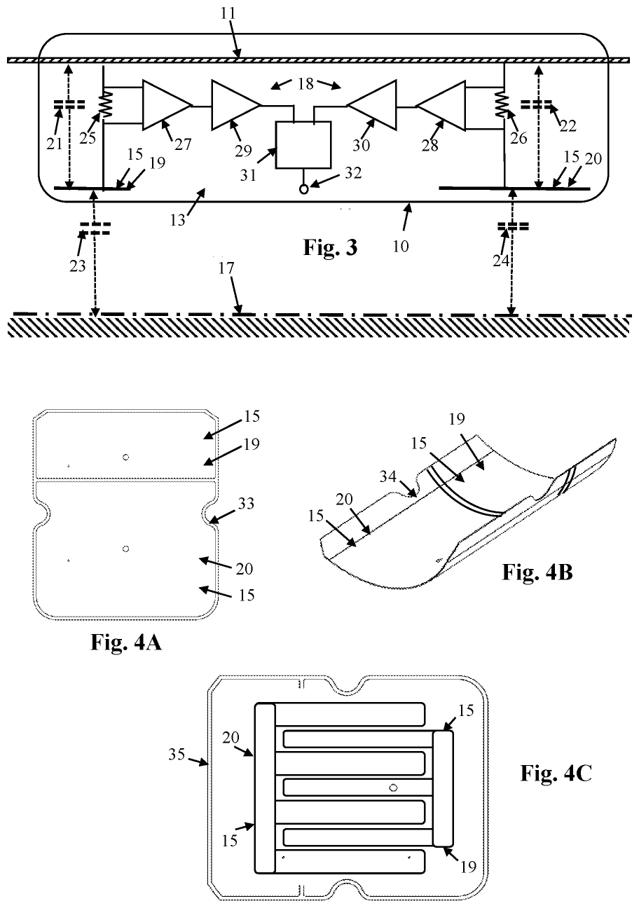

Reference is now made to FIG. 3, which is a second, nor detailed, simplified electric diagram of voltage measuring system 13, according to one exemplary embodiment.

As an option, the simplified electric diagram of FIG. 3 may be viewed in the context of the details of the previous Figures. Of course, however, the simplified electric diagram of FIG. 3 may be viewed in the context of any desired environment. Further, the aforementioned definitions may equally apply to the description below.

As shown in FIG. 2, voltage measuring system 13 may include at least two electrically conductive plates 15 typically formed with a metal layer or material. A first plate 15 designated by numeral 19 has an area A19 that is smaller (or larger) than the area A20 of a second plate 15 designated by numeral 20. It is appreciated that the number of plates 15 may be greater than two plates, and the areas of the various plates may vary accordingly.

Each plate 15 has an internal parasitic capacitance between the respective plate and cable 11 designated in FIG. 2 as internal parasitic capacitors 21 and 22. The different areas of capacitors 21 and 22 may result in different capacitances of capacitors 21 and 22 designated as C17 and C18 respectively. Each plate 15 has an external parasitic capacitance between the respective plate and reference point 17 designated in FIG. 2 as external parasitic capacitors 23 and 24.

As shown in FIG. 2, each plate may be connected to the electric cable 11 by a resistor. Resistor 25 may be connected between plate 19 and cable 11, and resistor 26 may be connected between plate 20 and cable 11.

Each resistor may be connected to input terminals of a respective electric input circuitry, or a buffer circuit 27 and 28, as shown in FIG. 2. Each such buffer circuit may include an operational amplifier. The outputs of the buffer circuits 27 and 28 may be connected to the input of a respective analog to digital converter (ADC) 29 and 30. The outputs of the ADCs 29 and 30 may be connected a processor (or microcontroller, etc.) 31. Each resistor, its buffer circuit, and its ADC may be regarded as current measuring devices 18 of FIG. 2.

Processor 31 may use buffer circuit 27 and ADC 29 to take measurements of the voltage V25 over resistor 25, and similarly use buffer circuit 28 and ADC 30 to take measurements of the voltage V26 over resistor 26. Processor 31 may then calculate electric current 125 through resistor 25, and electric current 126 through resistor 26. Processor 31 may then calculate electric voltage of cable 11 with respect to the potential of reference point 17 by comparing electric currents 125 and 126 (and optionally adding the voltage measured over resistors 25 and 26, respectively). Processor 31 may then communicate the calculated cable voltage via output 32 to any other type of computational equipment.

It is appreciated that alternatively a single ADC may be used with a switching circuitry connecting the single ADC to the two (or more) buffer circuits (27 and 28). Processor 31 may control the switching circuitry to select the appropriate buffer circuit 27 in an alternating manner to acquire current and/or voltage measurement of the respective resistor (25 and 26).

It is appreciated that the electric currents and/or voltages for resistors 25 and 26 can be calculated momentarily, or by way of averaging repeated measurements over time. For example by calculating RMS (root-mean-square) value of each of the currents and/or voltages. RMS values may be calculated by processor 31 or using dedicated hardware.

Reference is now made to FIG. 4A, FIG. 4B, and FIG. 4C, which are simplified illustrations of pairs of plates 15, according to three exemplary embodiments.

As an option, the simplified electric diagram of FIG. 4A, FIG. 4B, and FIG. 4C may be viewed in the context of the details of the previous Figures. Of course, however, the simplified electric diagram of FIG. 4A, FIG. 4B, and FIG. 4C may be viewed in the context of any desired environment. Further, the aforementioned definitions may equally apply to the description below.

FIG. 4A shows a printed circuit board (PCB) 33 that may include a pair of plates 15 of different sizes, such as plates 19 and 20 of FIG. 3. The two or more plates 15 may be formed on a single PCB with a space of few millimeters between the plates. The two or more plates 15 may be formed on the single PCB as thin layers of metal, or any other electrically conductive material.

FIG. 4B shows a printed circuit board 34 that may include a pair of plates 15 of different sizes, such as plates 19 and 20 of FIG. 3, and similar to FIG. 4A. However, printed circuit board 34 is curved. On one hand, the curved PCB 34 may conform to the shape of the external box of the cable device 10. On the other hand the curved PCB 34 may retain the same or similar external parasitic capacitance with the reference point when cable device 10 may tilt, such as when cable 11 swings sideways by the blowing wind. Therefore PCB 34 may provide more stable measurements in various whether conditions.

FIG. 4C shows a printed circuit board 35 that may include a pair of plates 15 of different sizes, such as plates 19 and 20 of FIG. 3, and similar to FIG. 4A and FIG. 4B. However, plates 19 and 20 of printed circuit board 35 are interleaved. Interleaving the two or more plates, in any shape and form of interleaving, may further enhance stable capacitance and accurate measurements in various weather conditions and cable motion such as galloping lines.

Other shapes and forms of the plurality of plates is contemplated.

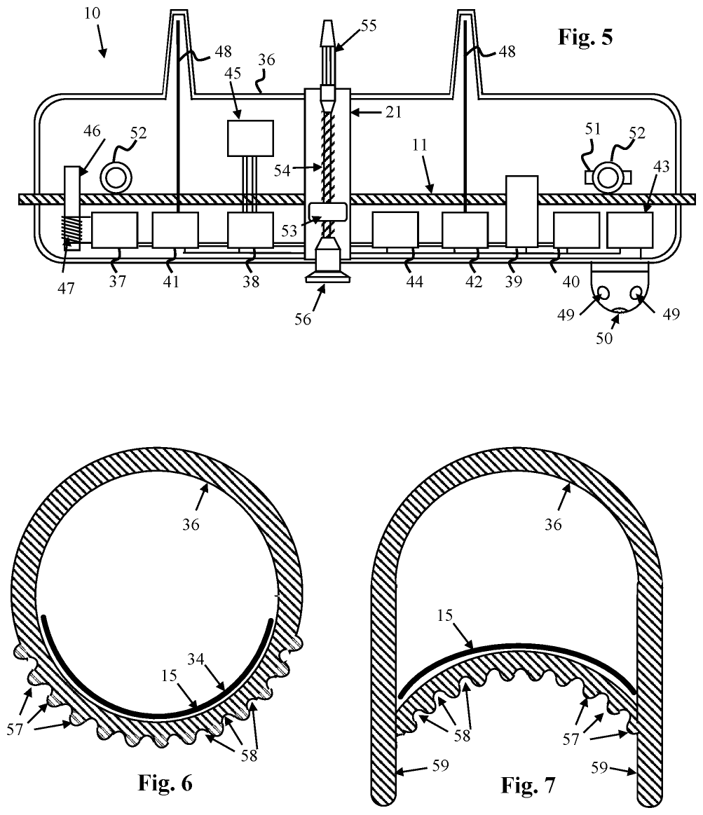

Reference is now made to FIG. 5, which is a simplified illustration of a cut through cable device 10 mounted on an electric cable 11, according to one exemplary embodiment.

As an option, the illustration of cable device 10 of FIG. 5 may be viewed in the context of the details of the previous Figures. Of course, however, the illustration of cable device 10 of FIG. 5 may be viewed in the context of any desired environment. Further, the aforementioned definitions may equally apply to the description below.

As shown in FIG. 5, the cable device 10 may include a box, or a body 36, through which the electric cable 11 passes. The electric cable 11 may be a part of an electric grid, an electric transmission network, or an electric distribution network, such as maintained by a power utility to provide electricity to the public, to industrial plants, etc. The cable device 10 may therefore be mounted on a live cable 11. That is, when cable 11 is fully powered and/or carries electric voltage and/or electric current.

The box 36 may be constructed of two parts which may be opened, and then closed around the cable 11. Alternatively, box 36 may be constructed of one part surrounding most of the cable diameter and having an opening at one side, such as slot 14 (not shown in FIG. 5), to insert cable 11 and attach the box to cable 11. Other constructions and shapes of box 36 are contemplated.

As shown in FIG. 5, the cable device 10 may include a power supply module 37, a controller module 38, one or more electric measuring devices 39, one or more physical measuring devices 40, and a backhaul communication module 41. Optionally, the cable device 10 may also include a local area communication module 42, a remote sensing module 43, and a propulsion control module 44. Optionally, the cable device 10 may also include cable clamping part 21, and a GPS module 45. Electric measuring devices 39 may include at least the electronic circuitry of cable voltage measuring systems 13, such as the electric circuitry shown and described with reference to FIG. 3.

As shown in FIG. 5, the cable device 10 may include a magnetic core 46 over which at least one coil is wrapped to form a winding 47. The magnetic core 46 may be mounted around the electric cable 11. The magnetic core 46 may be constructed from two parts, a part in each of the two parts of box 36 where the two parts of the magnetic core 46 are closed around electric cable 11 when box 36 is attached to electric cable 11. However, optionally, and particularly for a high voltage cable, magnetic core 46 may be open in the sense that it has a slot though which electric cable 11 may be inserted.

The magnetic core 46 typically derives magnetic field from the electric current flowing in the electric cable 11. Winding 47 may derives electric current from the magnetic flux in the magnetic core 46. Winding 47 may be electrically coupled to power supply module 37, typically providing electric voltage to other modules of cable device 46. It is appreciated that cable device 10 may derive electric power from a single electric cable 11.

Alternatively, for example when used with insulated high-voltage cables, and/or underground cables and/or low-voltage grids, power supply module 37 may be connected to sensors attached to electric cables deriving power supply from other sources such as a main unit connected to a low voltage output of a transformer, a battery, a photovoltaic (PV) element, etc. Such configuration of cable device 10 may have only one part with an opening at the bottom.

Backhaul communication module 41 and local area communication module 42 may be coupled, each and/or both, to one or more antennas 48. Remote sensing module 43 may be coupled to and control various sensors, one or more cameras 49, one or more microphones 50, etc. It is appreciated that a camera can be mounted on a system of axels providing three-dimensional rotation. Alternatively, a plurality, or an array, of fixed cameras can be mounted to cover a large field of view as needed.

Backhaul communication module 41 and local area communication module 42 may use any type of communication technology and/or communication network such as, but not limited to: The terms ‘communication technology’, or ‘communication network’, or simply ‘network’ refer to any type of communication medium, including but not limited to, a fixed (wire, cable) network, a wireless network, and/or a satellite network, a wide area network (WAN) fixed or wireless, including various types of cellular networks, a local area network (LAN) fixed or wireless including Wi-Fi, and a personal area network (PAN) fixes or wireless including Bluetooth, ZigBee, and NFC, power line carrier (PLC) communication technology, etc. The terms ‘communication network’, or ‘network’ may refer to any number of networks and any combination of networks and/or communication technologies.

Optionally, cable device 10 may also include a global positioning service (GPS) module 45 and may use it to measure, monitor, and/or control the position of the cable device 10 along electric cable 11. GPS module 45 may also provide an accurate universal clock, for example, for accurately determining absolute time of measurement.

Controller module 38 may include a processor unit, one or more memory units (e.g., random access memory (RAM), a non-volatile memory such as a Flash memory, etc.), one or more storage units (e.g. including a hard disk drive and/or a removable storage drive, etc.) as may be used to store and/or to execute a software program and associated data and to communicate with external devices. Controller module 38 may also function as processor 31 of FIG. 3. Alternatively, Controller module 38 may be electrically coupled to the output 32 of processor 31 of FIG. 3.

Propulsion control module 44 may be coupled to one or more actuating devices such as electric motor 51, which may be coupled to one or more wheels 52. Wheels 52 may be mounted on cable 11 to enable propulsion control module 44 to move the cable device 10 along cable 11 by controlling the electric motor 51.

It is appreciated that the propulsion system of cable device 10 (including, but not limited to propulsion control module 44, one or more electric motors 51 one or more wheels 52 etc.) may be operative to move cable device 10 along cable 11 and/or to rotate cable device 10 around cable 11.

It is appreciated that electric motor 51 represents herein any type of technology adequate to maneuver cable device 10 along and/or around cable 11, including, but not limited to, an AC motor, a DC motor, a stepper motor, a pneumatic pump and/or motor, a hydraulic pump and/or motor, or any other type of actuator.

Cable clamping part 21 may include, for example, a cable holder part 53 that may be pressed to cable 11 to firmly attach cable device 10 to cable 11. Cable holder part 53 may be maneuvered (e.g., up and down) by electrical means and/or by mechanical means such as a threaded rod 54. Threaded rod 54 may be operated by an electric actuator, or, as shown in FIG. 5, by a shaft 55 inserted into a socket of cable attachment actuator part 20. Alternatively, Threaded rod 54 may be operated by a rod inserted into socket 56. Cable holder part 53 may provide electrical coupling of voltage measuring system 13 to cable 11 as shown and described with reference to FIG. 3.

Reference is now made to FIG. 6, which is a simplified illustration of a side cut of box 36 showing the pair of plates 15 curved down in the form of curved PCB 34, according to one exemplary embodiment, and to FIG. 7, which is a simplified illustration of a side cut of box 36 showing the pair of plates 15 curved up, according to one exemplary embodiment.

As an option, the illustrations of FIG. 6 and FIG. 7 may be viewed in the context of the details of the previous Figures. Of course, however, the illustration of FIG. 6 and FIG. 7 may be viewed in the context of any desired environment. Further, the aforementioned definitions may equally apply to the description below.

As shown in FIG. 6 and FIG. 7, the bottom side of box 36 may include a plurality of parallel ridges 57 and troughs 58 to reduce the accumulation of precipitation such as rain and dew. FIG. 7 additionally shows that the bottom side of box 36 may include side walls 59 surrounding the bottom of box 36 to further reduce the accumulation of precipitation such as rain. It is appreciated that the body of FIG. 6 may also include such side walls.

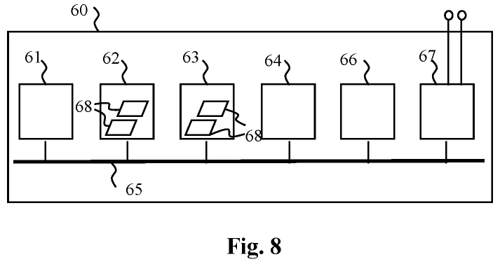

Reference is now made to FIG. 8, which is a simplified illustration of a computational device 60, typically included in box 36, according to one exemplary embodiment.

As an option, the illustrations of FIG. 8 may be viewed in the context of the details of the previous Figures. Of course, however, the illustration of FIG. 8 may be viewed in the context of any desired environment. Further, the aforementioned definitions may equally apply to the description below.

Computational device 60 is provided as an exemplary implementation of the processing part of cable device 10 and/or voltage measuring system 13. As shown in FIG. 8, computational device 60 may include at least one processor unit 61, one or more memory units 62 (e.g., random access memory (RAM), a non-volatile memory such as a Flash memory, etc.), one or more storage units 63 (e.g. including a hard disk drive and/or a removable storage drive, representing a floppy disk drive, a magnetic tape drive, a compact disk drive, a flash memory device, etc.).

Computational device 60 may also include one or more communication units 64. Such communication unit 64 may use any type of communication technology, particularly RF communication technology, particularly communication technology such as Wi-Fi, Bluetooth, ZigBee, and any remote-control communication technology as may be used by cable device 10 to communicate with any other cable device 10 or with a remote controller, a remote server, or any other computational device.

Computational device 60 may also include one or more communication buses 65 connecting the above units. Computational device 60 may also include one or more control circuitry 66 for controlling other devices coupled to, or included in, body 15.

Computational device 60 may also include electric circuitry 67 of voltage measuring system 13, as shown and described with reference to FIG. 3.

Computational device 60 may also include one or more computer programs 68, or computer control logic algorithms, which may be stored in any of the memory units 62 and/or storage units 63. Such computer programs, when executed, enable computing system 60 to perform various functions as set forth herein. Memory units 62 and/or storage units 63 and/or any other storage are possible examples of tangible computer-readable media. Particularly, computer programs 68 may include a software program and collected data for computing the cable voltage with respect to the reference point.

As disclosed above, the voltage measuring system 13 may include two or more metal plates 15 connected to the powerline 11 and facing the reference point, which may be the reference point 17 below the powerline. The plates may have different areas, which may be known. For example, the areas of the two plates may have a ratio of 1:2.

The plates may be mounted inside the cable device 10 enclosure with a non-conductive cover at the side pointing toward the reference point. The plates may be sealed from the environment by the cover and sealing. The plates may be thin and produced for example as a thin PCB. Using this PCB enables to curl the plates to form an arc so as to receive better measurements if the cable device 10 is hanging on the wire that is swinging due to wind. The two or more plates can be formed on a same, single, PCB with a space of few millimeter (for example) between the plates.

The plates may have the voltage potential of the power line 11 as each plate is connected through a low resistance current meter to the powerline. A parasitic impedance may be formed from each plate and the reference point. The voltage across each impedance may be close to the powerline's voltage.

To calculate the voltage, the voltage measuring system 13 may measure the currents flowing through each of the two or more plates to the reference point and the impedance between each of the two or more plates to the reference point. The currents and the impedances may be measured repeatedly and/or frequently as the impedance may change due to the environment changes, such as rain, snow, humidity, air pollution, etc.

By using two or more plates of different areas, and accurate current meters, the following equations may be solved, to calculate the cable voltage. A simplified version of the equations may be:

$$Vline = I 1 * Rp + I 1 * RL \qquad Eq . 1$$

$$Vline = I 2 * Rp + I 2 * A * RL \qquad Eq . 2$$

$$Result : Vline = C * I 1 * Rp * ( I 1 - I 2 ) / ( A * I 2 - I 1 )$$

Where:
I1 is the current of the big plate
I2 is the current of the smaller plate
A is the ratio between the plates' area after calibration and tilt adjustment
Rp is the resistance of measurement resistors 25 and 26 in FIG. 3)
RL is the impedance of the parasitic capacitor between the plates and the reference point.
C is an optional calibration factor for adjusting results during manufacturing calibrations.

The A parameter is based on the area ratio between the plates and is calibrated during manufacturing. During actual measurements, it is recommended to adjust the currents I1 and I2 by the tilt angle of the plates relative to the reference ground to get better results. If the plates tilt, the currents are a bit lower than when the plates are parallel to the ground reference plane. Dividing the currents by Cos (a), where a is the tilt angle, may improve the results.

For measuring the current a small resistor (i.e., 5 kOhm) may be connected between the powerline contact and each of the plates. Operational amplifiers may be provided where the two input terminals being connected to the two sides of each respective resistor. The output voltage of the operational amplifiers may be sampled at a sufficiently high sample rate by respective two Analog to Digital Converters (ADC). The sampling rate may typically be ten times the frequency of the powerline voltage (for an AC powerline).

A microprocessor may be connected to the outputs of the two (or more) ADCs to calculate average values such as RMS values of the voltage over each of the resistors and the respective currents. Alternatively, hardware components for computing RMS may be used. From the equations it is possible to extract the value of the impedance using the measured currents and then calculate the voltage.

It is appreciated that having the two or more metal plates may form respective parasitic capacitors between the plates and the device's body and/or between the plates and the powerline itself and these should be taken into account in the equations. These parasitic capacitors may be measured in an adequate laboratory as part of the calibration process of the voltage measuring system 13.

The manufacturing calibration of the process of the voltage measuring system 13 may also include calibrating the current measuring system(s), for example, using a precise signal generator injecting low voltage (for example 200 mVAC) to the plate's connector. Final calibration can be performed, for example, by attaching the cable device 10 to a powerline with low voltage (for example 500v) and calibrating the parasitic capacitors value.

When the plates are not positioned in parallel to the reference point, the projected area of the plates is smaller by the angle of the tilt, and therefore the parasitic capacitance to the reference point may change. To resolve such problem, the cable device 10 may be additionally equipped with a 3D accelerometer and/or a 3D gyro to measure the tilt, roll and pitch of the cable device 10. Measurements of tilt, roll and pitch of the cable device 10 may be used to correct the measurements of the currents when the device is positioned in a slope of the line, or the line and the cable device 10 are tilted by the wind, or galloping.

To further reduce dis-alignment between the two (or more) plates 15 due to tilt, roll and/or pitch, the plates may be arranged in interleaving mode, such as device 35 of FIG. 4C.

The bottom cover of the plates, which may be non-conductive, may be made from water repelling (hydrophobic) material, or coated with repelling (hydrophobic) material, such as Teflon or a similar material.

It is appreciated that certain features, which are, for clarity, described in the context of separate embodiments, may also be provided in combination in a single embodiment. Conversely, various features, which are, for brevity, described in the context of a single embodiment, may also be provided separately or in any suitable sub-combination.

Although the invention has been described in conjunction with specific embodiments thereof, it is evident that many alternatives, modifications, and variations will be apparent to those skilled in the art. Accordingly, it is intended to embrace all such alternatives, modifications and variations. All publications, patents and patent applications mentioned in this specification are herein incorporated in their entirety by reference into the specification, to the same extent as if each individual publication, patent, or patent application was specifically and individually indicated to be incorporated herein by reference. In addition, citation, or identification of any reference in this application shall not be construed as an admission that such reference is available as prior art.

What is claimed is:

1. A voltage measuring device for measuring voltage of an electric cable of an electric grid, the voltage measuring device comprising:
a first plate having a first area and providing a first capacitance between the first plate and a reference point;
at least a second plate having a second area and providing a second capacitance between the second plate and the reference point;
at least one current measuring device for measuring current via each of the first plate and second plate for providing respective first and second current measurements;
a processor electrically coupled to the at least one current measuring device for receiving the first and the second current measurements and for calculating the voltage between the electric cable and the reference point by comparing the first and the second current measurements.

2. The voltage measuring device according to claim 1, wherein the voltage measuring device is mounted on the electric cable of the electric grid.

3. The voltage measuring device according to claim 1, wherein the voltage measuring device is not electrically connected to the reference point.

4. The voltage measuring device according to claim 1, wherein at least one of the first plate and the second plate is facing the reference point and is curled so that the at least one of the first plate and the second plate faces the reference point when at least one of the voltage measuring device, the first plate and the second plate performs at least one of yaw, pitch and roll.

5. The voltage measuring device according to claim 1, wherein the first plate and the second plate are interleaved with each other.

6. The voltage measuring device according to claim 4, additionally comprising:
at least one of an accelerometer and a gyro for measuring the at least one of yaw, pitch and roll of the at least one of the voltage measuring devices and the plates; and
the processor of the voltage measuring device being operative to calculate the voltage between the electric cable and the reference point according to the measured yaw, pitch and/or roll.

7. The voltage measuring device according to claim 1, wherein the processor monitors relation between current measurements to detect at least one of a fault and weather condition comprising at least one of humidity, rain, and ice.

8. The voltage measuring device according to claim 1, wherein the processor uses at least one of the current measurements, the calculated the voltage between the electric cable and the reference point, and the capacitance between the plates and the reference point, to calculate high-speed changes of the voltage between the electric cable and the reference point.

9. The voltage measuring device according to claim 1, additionally comprising:
measuring in a laboratory capacitance between each of the plates and the electric cable to form internal capacitance values; and
providing the internal capacitance values to the processor for calculating the voltage between the electric cable and the reference point.

10. A computer-implemented method for measuring voltage between an electric cable of an electric grid and a reference point, the method comprising:
mounting on the electric cable a voltage measuring device comprising:
a first plate having a first area and providing a first capacitance between the cable and the reference point;
a second plate having a second area and providing a second capacitance between the cable and the reference point;
at least one current measuring device for measuring current via each of the first plate and second plate for providing respective first and second current measurements; and
a processor electrically coupled to the at least one current measuring device for receiving the current measurements and for calculating the voltage between the electric cable and the reference point;
wherein the first plate has a first area and provides a first capacitance between the plate and the reference point;
wherein the second plate has a second area and provides a second capacitance between the plate and the reference point; and
wherein the processor calculates the voltage between the electric cable and the reference point by comparing the current measurements.

11. A computer program product embodied on a non-transitory computer readable medium, including instructions that, when executed by at least one processor, cause the processor to perform operations comprising:
receiving at least two current measurements, the at least two current measurements being measured by at least one current measuring device electrically coupled to at least a first plate and a second plate, wherein the first plate has a first area and provides a first capacitance between the first plate and the reference point, and wherein the second plate has a second area and provides a second capacitance between the second plate and the reference point; and
wherein the processor calculates the voltage between the electric cable and the reference point by comparing the at least two current measurements.
